(19) United States
(12) Patent Application Publication
(10) Pub. No.: US 2012/0250249 A1
(43) Pub. Date: Oct. 4, 2012

(54) BATTERY

(75) Inventors: Zheng-Heng SUN, Tu-Cheng (TW); Lei LIU, Shenzhen (CN)

(73) Assignees: HON HAI PRECISION INDUSTRY CO., LTD., Tu-Cheng (TW); HONG FU JIN PRECISION INDUSTRY (ShenZhen) CO., LTD., Shenzhen City (CN)

(21) Appl. No.: 13/117,143

(22) Filed: May 27, 2011

(30) Foreign Application Priority Data
Apr. 2, 2011 (CN) 201110083102.0

(51) Int. Cl. H05K 7/00

(52) U.S. Cl. 361/679.55

(57) ABSTRACT

A battery is installed in a notebook computer to power the notebook computer. The battery includes a casing defining a USB port and a power source interface, and a cell assembly received in the casing. The USB port is electrically connected to the cell assembly to charge an electronic device. The power interface connected to a power source is electrically connected to the cell assembly to charge the cell assembly.

### BACKGROUND

1. Technical Field

The present disclosure relates to batteries, particularly to a battery for a notebook computer.

2. Description of Related Art

Notebook computers can usually be operated using a battery. Another electronic device, such as a mobile phone can be charged through a USB connector coupled to a motherboard of the notebook computer only when the notebook computer is on. If the battery does not have enough charge to power the notebook computer, then the mobile phone cannot be charged by the battery of the notebook computer. Therefore, it is inconvenient to charge the mobile phone through the notebook.

### BRIEF DESCRIPTION OF THE DRAWINGS

Many aspects of the present embodiments can be better understood with reference to the following drawings. The components in the drawings are not necessarily drawn to scale, the emphasis instead being placed upon clearly illustrating the principles of the present embodiments. Moreover, in the drawings, all the views are schematic, and like reference numerals designate corresponding parts throughout the several views.

FIG. 1 is an assembled, isometric view of an exemplary embodiment of a battery, and a notebook computer.

FIG. 2 is an exploded view of FIG. 1.

FIG. 3 is a block diagram of a circuit diagram of the battery of FIG. 1.

### DETAILED DESCRIPTION

The present disclosure, including the accompanying drawings, is illustrated by way of examples and not by way of limitation. It should be noted that references to “an” or “one” embodiment in this disclosure are not necessarily to the same embodiment, and such references mean at least one.

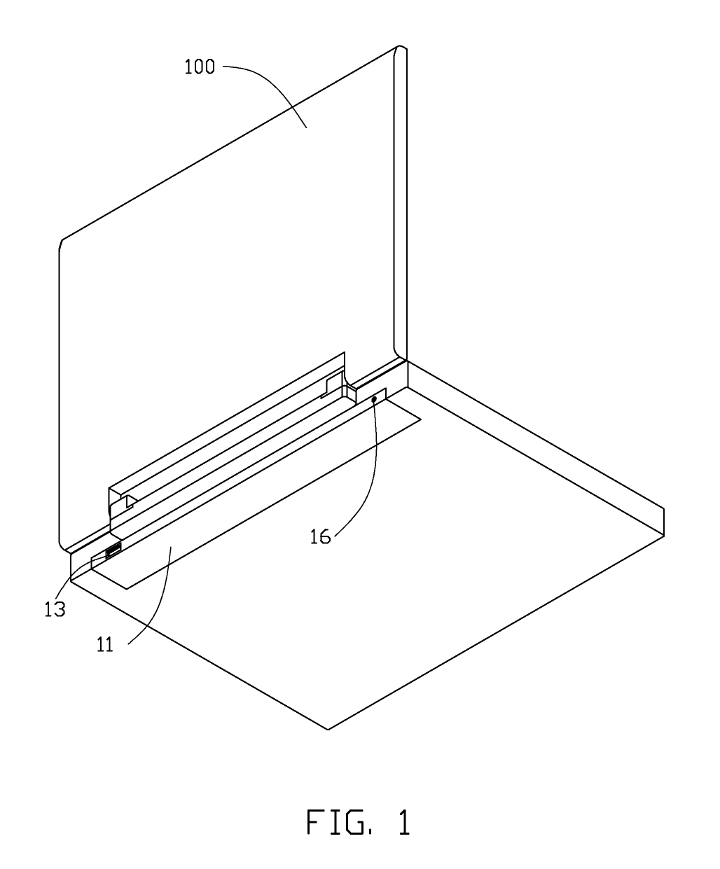

Referring to FIG. 1, an exemplary embodiment of a battery is installed in a notebook computer 100 to power the notebook computer 100.

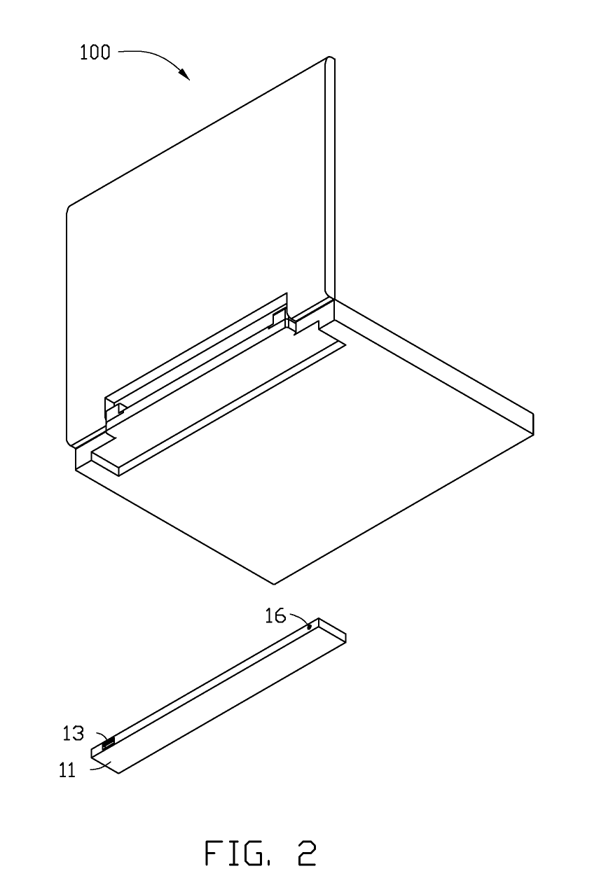

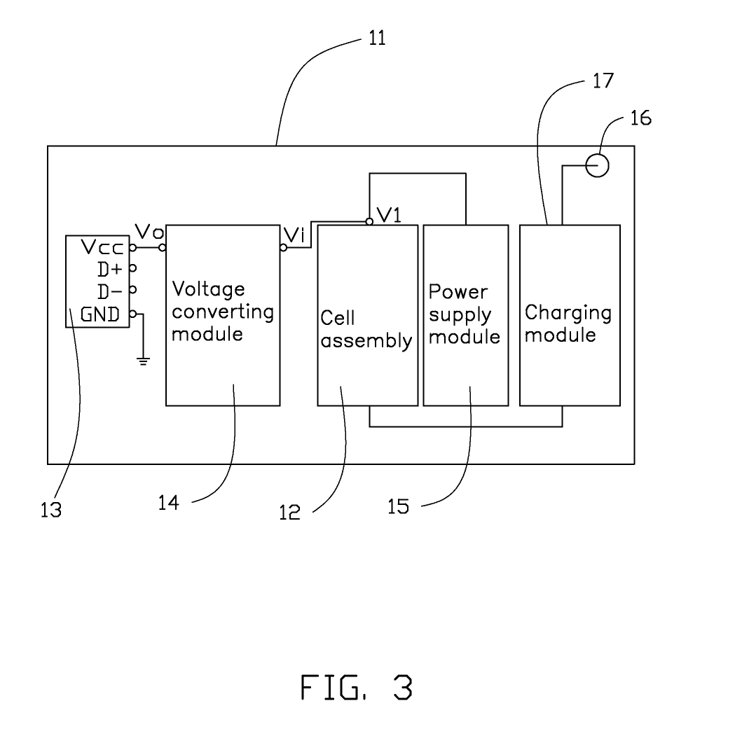

Referring to FIGS. 2 and 3, the battery includes a substantially rectangular casing 11 defining a USB port 13 and a power source interface 16, and a cell assembly 12 received in the casing 11. A voltage converting module 14, a power supply module 15, and a charging module 17 are arranged in the casing 11. An output terminal V1 of the cell assembly 12 is connected to an input terminal Vi of the voltage converting module 14. An output terminal Vo of the voltage converting module 14 is connected to the power terminal Vcc of the USB port 13. Therefore, the voltage output from the cell assembly 12 is converted to a standard working voltage of the USB port 13 by the voltage converting module 14 to power the USB port 13. The output terminal V1 of the cell assembly 12 is also connected to the power supply module 15 which powers the notebook computer 100. The charging module 17 is also connected to the power source interface 16 and the cell assembly 12. A power source is connected to the power source interface 16 to charge the cell assembly 12 through the charging module 17.

Since the USB port 13 is electrified by the cell assembly 12 via the voltage converting module 14, another electronic device, such as a mobile phone can be charged through the USB port 13, even when the notebook computer 100 is off.

It is to be understood, however, that even though numerous characteristics and advantages of the embodiments have been set forth in the foregoing description, together with details of the structure and function of the embodiments, the present disclosure is illustrative only, and changes may be made in details, especially in matters of shape, size, and arrangement of parts within the principles of the embodiments to the full extent indicated by the broad general meaning of the terms in which the appended claims are expressed.

What is claimed is:

1. a battery mounted in a notebook computer to power the notebook, the battery comprising:
a casing defining a USB port and a power source interface; and
a cell assembly received in the casing, and electrically connected to the USB port and the power source interface;
wherein the USB port is to be connected to an electronic device to be charged; the power source interface is adapted to connected to a power source to charge the cell assembly.

2. The battery of claim 1, further comprising a voltage converting module arranged in the casing, and connected between the cell assembly and the USB port to convert a voltage output from the cell assembly to a standard working voltage of the USB port.

3. The battery of claim 2, further comprising a power supply module arranged in the casing, and connected to the cell assembly, wherein the cell assembly powers the notebook computer through the power supply module.

4. The battery of claim 3, further comprising a charging module arranged in the casing, and connected between the power source interface and the cell assembly to convert a voltage of the power source to a voltage to charge the cell assembly.
